(19) United States
(12) Patent Application Publication
(10) Pub. No.: US 2025/0031550 A1
(43) Pub. Date: Jan. 23, 2025

(54) DISPLAY DEVICE AND METHOD FOR FABRICATION THEREOF

(71) Applicant: Samsung Display Co., LTD., Yongin-si (KR)

(72) Inventors: Su Kyoung YANG, Yongin-si (KR); Joon Yong PARK, Yongin-si (KR); Hyun Eok SHIN, Yongin-si (KR); Dong Min LEE, Yongin-si (KR); Ju Hyun LEE, Yongin-si (KR)

(73) Assignee: Samsung Display Co., LTD., Yongin-si (KR)

(21) Appl. No.: 18/602,028

(22) Filed: Mar. 12, 2024

(30) Foreign Application Priority Data
Jul. 21, 2023 (KR) 10-2023-0095133

(51) Int. Cl. H10K 59/80; H10K 59/12; H10K 59/122

(52) U.S. Cl. CPC H10K 59/80521; H10K 59/1201; H10K 59/122; H10K 59/80523; H10K 59/80524

(57) ABSTRACT

A display device that includes a first pixel electrode disposed on a substrate; a pixel defining layer disposed on the substrate and exposing the first pixel electrode; a first light emitting layer disposed on the first pixel electrode; a first common electrode disposed on the first light emitting layer; a first bank layer disposed on the pixel defining layer; a second bank layer disposed on the first bank layer and including a side surface protruding from a side surface of the first bank layer; and a third bank layer disposed on the second bank layer and including a side surface protruding from the side surface of the first bank layer, wherein the second bank layer and the third bank layer each include a transparent conductive oxide (TCO), and the second bank layer further includes zinc (Zn).

### CROSS-REFERENCE TO RELATED APPLICATIONS

This application claims priority under 35 U.S.C. § 119 from Korean Patent Application No. 10-2023-0095133 filed on Jul. 21, 2023 in the Korean Intellectual Property Office, the entire contents of which are incorporated herein by reference.

### BACKGROUND

### 1. Technical Field

The disclosure relates to a display device and a method for fabrication thereof.

### 2. Description of the Related Art

With the advance of information-oriented society, more and more demands may be placed on display devices for displaying images in various ways. For example, display devices may be employed in various electronic devices such as smartphones, digital cameras, laptop computers, navigation devices, and smart televisions. The display device may be a flat panel display device such as a liquid crystal display device, a field emission display device and an organic light emitting display device. Among the flat panel display devices, in the light emitting display device, since each of pixels of a display panel includes a light emitting element capable of emitting light by itself, an image can be displayed without a backlight part providing light to the display panel.

Recently, the display device may be employed in a glass-type device for providing virtual reality and augmented reality. In order to be employed in the glass-type device, the display device needs to be implemented in a very small size of about 2 inches or less, or needs to have a high number of pixels per inch (PPI) to be implemented with high resolution. For example, the display device may have about 1,000 pixels per inch (PPI) or more.

In this way, in case that the display device is implemented in a very small size or has a high PPI, it may be difficult to implement light emitting elements separated for each emission area (i.e., spaced apart from each other) by a mask process because the area of the emission area where the light emitting element may be disposed is reduced.

### SUMMARY

Aspects of the disclosure provide a display device capable of forming light emitting elements spaced apart from each other for each emission area without a mask process.

Aspects of the disclosure provide a display device having high light efficiency.

Aspects of the disclosure also provide a display device in which emission variation that may occur in each pixel due to damage to a bank structure by an etching process performed during a fabrication process of a display device may be reduced.

However, aspects of the disclosure may not be restricted to those set forth herein. The above and other aspects of the disclosure will become more apparent to one of ordinary skill in the art to which the disclosure pertains by referencing the detailed description of the disclosure given below.

According to an aspect of the disclosure, a display device may include a first pixel electrode disposed on a substrate; a pixel defining layer disposed on the substrate, and exposing the first pixel electrode; a first light emitting layer disposed on the first pixel electrode; a first common electrode disposed on the first light emitting layer; a first bank layer disposed on the pixel defining layer; a second bank layer disposed on the first bank layer and including a side surface protruding from a side surface of the first bank layer; and a third bank layer disposed on the second bank layer and including a side surface protruding from the side surface of the first bank layer, wherein the second bank layer and the third bank layer may include a transparent conductive oxide (TCO), and the second bank layer further include zinc (Zn).

The third bank layer may further include hydrogen.

A ratio of zinc (Zn) in the second bank layer may be in a range of about 5 at % to about 50 at % with respect to a total number of atoms.

The side surface of the second bank layer and the side surface of the third bank layer may be aligned with each other in a plan view.

The second bank layer and the third bank layer may be amorphous, and a combined visible light transmittance of the second bank layer and the third bank layer may be about 85% or more.

The third bank layer may include hydrogen and indium tin oxide (ITO).

A thickness of the third bank layer may be greater than a thickness of the second bank layer.

A sum of a thickness of the second bank layer and a thickness of the third bank layer may be in a range of about 500 Å to about 1500 Å.

The first bank layer may include metal.

The first common electrode may be in contact with the first bank layer.

A thickness of the first bank layer may be in a range of about 4000 Å to about 7000 Å.

The display device may further comprise a first organic pattern disposed on the third bank layer, the first organic pattern and the first light emitting layer may include a same material; and a first electrode pattern disposed on the first organic pattern, the first electrode and the first common electrode may include a same material, wherein the first light emitting layer and the first organic pattern may be spaced apart from each other, and the first common electrode and the first electrode pattern may be spaced apart from each other.

According to an aspect of the disclosure, a display device comprises a first pixel electrode disposed on a substrate; a pixel defining layer disposed on the substrate, and exposing the first pixel electrode; a first light emitting layer disposed on the first pixel electrode; a first common electrode disposed on the first light emitting layer; a first bank layer disposed on the pixel defining layer; a second bank layer disposed on the first bank layer, and comprising a side surface protruding from a side surface of the first bank layer; and a third bank layer disposed on the second bank layer, and comprising a side surface protruding from the side surface of the first bank layer, wherein a thickness of the first bank layer may be greater than a sum of a thickness of the second bank layer and a thickness of the third bank layer, and the thickness of the third bank layer may be greater than the thickness of the second bank layer.

The first bank layer may include an opaque metal, and the second bank layer and the third bank layer may each include transparent conductive oxide (TCO).

The thickness of the first bank layer may be greater than or equal to about three times the sum of the thickness of the second bank layer and the thickness of the third bank layer.

The display device may further comprise a second pixel electrode disposed on the substrate, the second pixel electrode and the first pixel electrode may be spaced apart from each other; a second light emitting layer disposed on the second pixel electrode; a second common electrode disposed on the second light emitting layer, the second common electrode and the first common electrode may be spaced apart from each other; a first inorganic layer disposed on each of the first common electrode and the third bank layer; and a second inorganic layer disposed on each of the second common electrode and the third bank layer, wherein the first inorganic layer and the second inorganic layer may be spaced apart from each other, a part of the third bank layer may be exposed in a separation space between the first inorganic layer and the second inorganic layer, and a thickness of the second bank layer overlapping the first inorganic layer and a thickness of the second bank layer overlapping the second inorganic layer may be equal.

According to an aspect of the disclosure, a method for fabrication of a display device may comprise forming a plurality of pixel electrodes spaced apart from each other on a substrate, forming a sacrificial layer disposed on the plurality of pixel electrodes, forming a pixel defining material layer on the sacrificial layer, forming a first bank material layer on the pixel defining material layer, forming a second bank material layer on the first bank material layer, forming a third bank material layer on the second bank material layer; etching the second bank material layer and the third bank material layer in an area overlapping the plurality of pixel electrodes; etching the first bank material layer in the area overlapping the plurality of pixel electrodes; etching a side surface of the first bank material layer to partially expose a bottom surface of the second bank material layer; etching the pixel defining material layer; etching the sacrificial layer to expose the plurality of pixel electrodes; forming a first light emitting layer on one of the plurality of pixel electrodes, forming a first common electrode on the first light emitting layer, and forming a first inorganic material layer on the first common electrode.

The forming of the third bank material layer on the second bank material layer may comprise sputtering under a mixed gas atmosphere comprising hydrogen and argon, the third bank material layer may include hydrogen and indium tin oxide.

The etching of the second bank material layer and the third bank material layer in the area overlapping the plurality of pixel electrodes may comprise exposing a part of the first bank material layer by removing the second bank material layer and the third bank material layer through a wet etching technique, and the etching of the first bank material layer in the area overlapping the plurality of pixel electrodes may comprise removing the exposed first bank material layer by a dry etching technique.

The forming of the first light emitting layer on the one of the plurality of pixel electrodes may comprise forming a first organic pattern material layer on the third bank material layer, the first organic pattern material layer being spaced apart from the first light emitting layer. The forming of the first common electrode on the first light emitting layer may comprise forming a first electrode pattern material layer on the first organic pattern material layer, the first electrode pattern material layer being spaced apart from the first common electrode, and the forming of the first inorganic material layer on the first common electrode may comprise forming the first inorganic material layer seamlessly connected on the first common electrode and the first electrode pattern material layer.

In accordance with the display device and the method for fabrication thereof according to an embodiment, a second bank layer and a third bank layer including a transparent material may be included, so that it may be possible to reduce a pixel gap and improve light efficiency.

Further, in accordance with the display device and the method for fabrication thereof according to an embodiment, the second bank layer of the bank structure may not be damaged during the fabrication process, so that it may be possible to prevent a tip from being bent. The luminance difference between light emitting elements may be reduced by securing a sufficient contact area between a common electrode and the bank structure.

However, effects according to the embodiments of the disclosure may not be limited to those exemplified above and various other effects may be incorporated herein.

### BRIEF DESCRIPTION OF THE DRAWINGS

The above and other aspects and features of the disclosure will become more apparent by describing in detail embodiments thereof with reference to the attached drawings, in which:

FIG. 1 is a perspective view illustrating a display device according to an embodiment;

FIG. 2 is a schematic cross-sectional view of the display device of FIG. 1 viewed from a side;

FIG. 3 is a plan view showing the arrangement of light emitting elements, a pixel defining layer, trace patterns, and a third bank layer in the display area of the display device according to an embodiment;

FIG. 4 is a schematic cross-sectional view taken along line B-B′ of FIG. 3 illustrating a part of a display device according to an embodiment;

FIG. 5 is an enlarged view showing a first emission area, i.e., area A1, of FIG. 4;

FIG. 6 is an enlarged view showing a first emission area according to an embodiment;

FIG. 7 is a schematic cross-sectional view of a case where the second bank layer includes an opaque metal;

FIG. 8 is a flowchart showing a fabrication process of a display device according to an embodiment; and

FIGS. 9 to 18 are schematic cross-sectional views sequentially showing a fabrication process of a display device according to an embodiment.

### DETAILED DESCRIPTION OF THE EMBODIMENTS

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. In case that an embodiment may be implemented differently, a specific process order may be performed differently from the described order. For example, two consecutively described processes may be performed substantially at the same time or performed in an order opposite to the described order. Also, like reference numerals and/or reference characters denote like elements.

In case that an element, such as a layer, is referred to as being “on,” “connected to,” or “coupled to” another element or layer, it may be directly on, connected to, or coupled to the other element or layer or intervening elements or layers may be present. In case that, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the X-axis, the Y-axis, and the Z-axis are not limited to three axes of a rectangular coordinate system, such as the x, y, and z axes, and may be interpreted in a broader sense. For example, the X-axis, the Y-axis, and the Z-axis may be perpendicular to one another, or may represent different directions that may not be perpendicular to one another.

For the purposes of this disclosure, “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” in case that used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, may not be necessarily intended to be limiting.

As customary in the field, some embodiments are described and illustrated in the accompanying drawings in terms of functional blocks, parts, and/or modules. Those skilled in the art will appreciate that these blocks, parts, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, parts, and/or modules being implemented by microprocessors or other similar hardware, they may be programmed and controlled using software (e.g., microcode) to perform various functions discussed herein and may optionally be driven by firmware and/or software. It is also contemplated that each block, part, and/or module may be implemented by dedicated hardware, or as a combination of dedicated hardware to perform some functions and a processor (e.g., one or more programmed microprocessors and associated circuitry) to perform other functions. Also, each block, part, and/or module of some embodiments may be physically separated into two or more interacting and discrete blocks, parts, and/or modules without departing from the scope of the inventive concepts. Further, the blocks, parts, and/or modules of some embodiments may be physically combined into more complex blocks, parts, and/or modules without departing from the scope of the inventive concepts.

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly so defined herein.

Hereinafter, embodiments will be described with reference to the accompanying drawings.

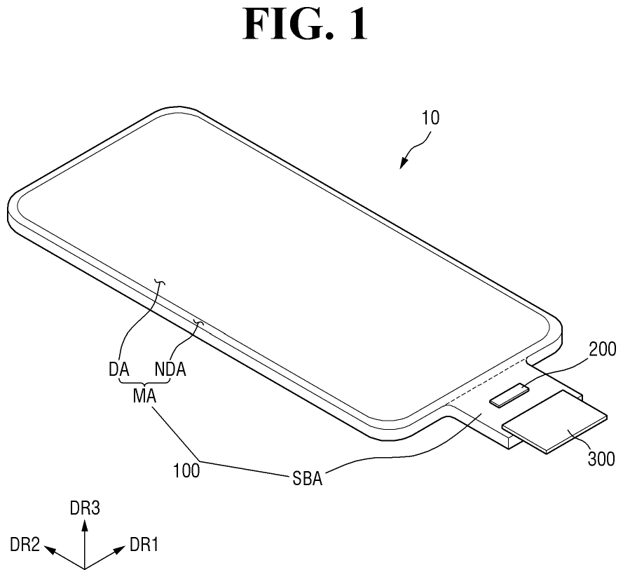

FIG. 1 is a perspective view illustrating a display device according to an embodiment.

Referring to FIG. 1, a display device 10 according to an embodiment may be included in an electronic device and may provide a screen displayed on the electronic device. The electronic device may refer to any electronic device providing a display screen. Examples of the electronic device may include a television, a laptop computer, a monitor, a billboard, an Internet-of-Things device, a mobile phone, a smartphone, a tablet personal computer (PC), an electronic watch, a smart watch, a watch phone, a head-mounted display, a mobile communication terminal, an electronic notebook, an electronic book, a portable multimedia player (PMP), a navigation device, a game machine, a digital camera, a camcorder and the like, which provide a display screen.

The shape of the display device 10 may be variously modified. For example, the display device 10 may have a shape similar to a rectangular shape having a short side in a first direction DR1 and a long side in a second direction DR2. The edge where the short side in the first direction DR1 and the long side in the second direction DR2 meet at a corner that may be rounded to have a curvature, but may not be limited thereto and may be formed at a right angle. The planar shape of the display device 10 may not be limited to a quadrilateral shape, and may be formed to have a shape similar to another polygonal shape, a circular shape, or elliptical shape.

The display device 10 may include a display panel 100, a display driver 200, a circuit board 300, and a touch driver 400.

The display panel 100 may include a main region MA and a sub-region SBA.

The main region MA may include a display area DA including pixels displaying an image and a non-display area NDA disposed around the display area DA. The display area DA may emit light from multiple emission areas or multiple opening areas. For example, the display panel 100 may include a pixel circuit including switching elements, a pixel defining layer defining an emission area or an opening area, and a self-light emitting element.

For example, the self-light emitting element may include at least one of an organic light emitting diode (LED) including an organic light emitting layer, a quantum dot LED including a quantum dot light emitting layer, an inorganic LED including an inorganic semiconductor, or a micro LED, but may not be limited thereto.

Multiple pixels, multiple scan lines, multiple data lines, and multiple power lines may be disposed in the display area DA. Each of the pixels may be defined as a minimum unit that emits light, and each of the above-described self-light emitting elements may each be a pixel. The scan lines may supply a scan signal received from a scan driver to the pixels. The data lines may supply the data voltages received from the display driver 200 to the pixels. The power lines may supply the power voltages received from the display driver 200 to the pixels.

The non-display area NDA may be an area outside the display area DA. The non-display area NDA may be defined as an edge area of the main region MA of the display panel 100. The non-display area NDA may include a scan driver that supplies scan signals to the scan lines, and fan-out lines that connect the display driver 200 to the display area DA.

The sub-region SBA may be a region extending from a side of the main region MA. The sub-region SBA may include a flexible material which can be bent, folded or rolled. For example, in case that the sub-region SBA is bent, the sub-region SBA may overlap the main region MA in a thickness direction (third direction DR3). The sub-region SBA may include the display driver 200 and a pad portion electrically connected to the circuit board 300. In an embodiment, the sub-region SBA may be omitted, and the display driver 200 and the pad portion may be arranged in the non-display area NDA.

The display driver 200 may output signals and voltages for driving the display panel 100. The display driver 200 may supply data voltages to data lines. The display driver 200 may supply a power voltage to the power line and may supply a scan control signal to the scan driver. The display driver 200 may be formed as an integrated circuit (IC) and mounted on the display panel 100 by a chip on glass (COG) method, a chip on plastic (COP) method, or an ultrasonic bonding method. For example, the display driver 200 may be disposed in the sub-region SBA, and may overlap the main region MA in the thickness direction (third direction DR3) by bending of the sub-region SBA. For another example, the display driver 200 may be mounted on the circuit board 300.

The circuit board 300 may be attached to the pad portion of the display panel 100 by using an anisotropic conductive film (ACF). Lead lines of the circuit board 300 may be electrically connected to a pad portion of the display panel 100. The circuit board 300 may be a flexible printed circuit board, a printed circuit board, or a flexible film such as a chip on film.

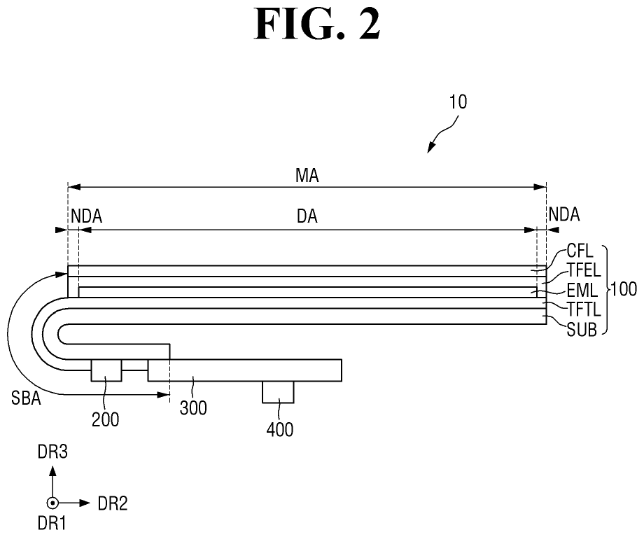

FIG. 2 is a schematic cross-sectional view of the display device of FIG. 1 viewed from the side.

Referring to FIG. 2, the display panel 100 may include a substrate SUB, a thin film transistor layer TFTL, a light emitting element layer EML, a thin film encapsulation layer TFEL, and a color filter layer CFL.

The substrate SUB may be a base substrate or a base member. The substrate SUB may be a flexible substrate which can be bent, folded or rolled. For example, the substrate SUB may include a polymer resin such as polyimide (PI), but may not be limited thereto. In an embodiment, the substrate SUB may include a glass material or a metal material.

The thin film transistor layer TFTL may be disposed on the substrate SUB. The thin film transistor layer TFTL may include multiple thin film transistors constituting a pixel circuit of pixels. The thin film transistor layer TFTL may further include scan lines, data lines, power lines, scan control lines, fan-out lines that connect the display driver 200 to the data lines, and lead lines that connect the display driver 200 to the pad portion. Each of the thin film transistors may include a semiconductor region, a source electrode, a drain electrode, and a gate electrode. For example, in case that the scan driver is formed on a side of the non-display area NDA of the display panel 100, the scan driver may include thin film transistors.

The thin film transistor layer TFTL may be disposed in the display area DA, the non-display area NDA, and the sub-region SBA. Thin film transistors, scan lines, data lines, and power lines of each of the pixels of the thin film transistor layer TFTL may be disposed in the display area DA. The scan control lines and fan-out lines of the thin film transistor layer TFTL may be disposed in the non-display area NDA. The lead lines of the thin film transistor layer TFTL may be disposed in the sub-region SBA.

The light emitting element layer EML may be disposed on the thin film transistor layer TFTL. The light emitting element layer EML may include multiple light emitting elements each including a first electrode, a second electrode, and a light emitting layer to emit light, and a pixel defining layer defining pixels. The light emitting elements of the light emitting element layer EML may be disposed in the display area DA.

In an embodiment, the light emitting layer may be an organic light emitting layer including an organic material. The light emitting layer may include a hole transporting layer, an organic light emitting layer, and an electron transporting layer. In case that the first electrode receives a voltage through the thin film transistor of the thin film transistor layer TFTL and the second electrode receives the cathode voltage, holes and electrons may be transferred to the organic light emitting layer through the hole transporting layer and the electron transporting layer, respectively and may be combined with each other to emit light in the organic light emitting layer.

In an embodiment, the light emitting elements may include a quantum dot light emitting diode including a quantum dot light emitting layer, an inorganic light emitting diode including an inorganic semiconductor, or a micro light emitting diode.

The thin film encapsulation layer TFEL may cover the top surface and the side surface of the light emitting element layer EML, and may protect the light emitting element layer EML. The thin film encapsulation layer TFEL may include at least an inorganic layer and at least an organic layer for encapsulating the light emitting element layer EML.

The color filter layer CFL may be disposed on the thin film encapsulation layer TFEL. The color filter layer CFL may include multiple color filters respectively corresponding to the emission areas. Each of the color filters may selectively transmit light of a specific wavelength and may block or absorb light of a different wavelength. The color filter layer CFL may absorb a part of light coming from the outside of the display device 10 to reduce reflected light due to external light. Accordingly, the color filter layer CFL may prevent color distortion caused by reflection of the external light.

Since the color filter layer CFL may be disposed (e.g., directly disposed) on the thin film encapsulation layer TFEL, the display device 10 may not require a separate substrate for the color filter layer CFL. Accordingly, the thickness of the display device 10 may be relatively small.

In some embodiments, the display device 10 may further include an optical device. The optical device may emit or receive light in infrared, ultraviolet, and visible light bands. For example, the optical device may be an optical sensor that detects light incident on the display device 10 such as a proximity sensor, an illuminance sensor, a camera sensor, a fingerprint sensor, or an image sensor.

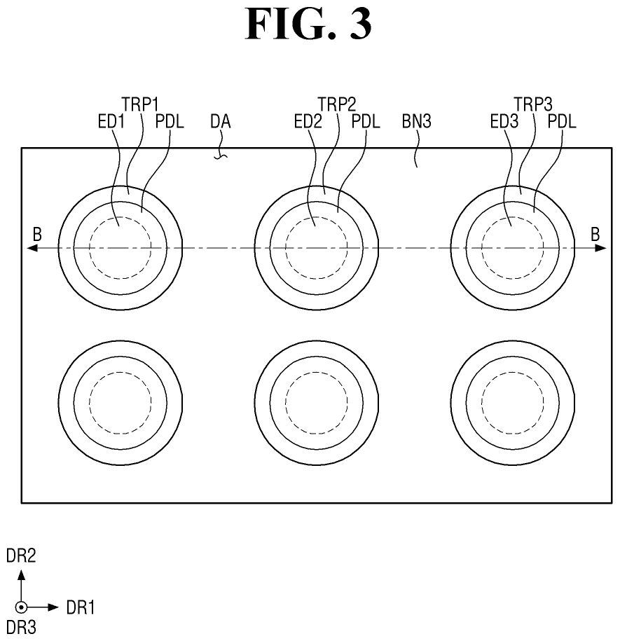

FIG. 3 is a plan view illustrating a part of a display device according to an embodiment. FIG. 3 is a plan view showing the arrangement of light emitting elements ED1, ED2, and ED3, a pixel defining layer PDL, trace patterns TRP1, TRP2, and TRP3, and a third bank layer BN3 in the display area DA of the display device 10.

Referring to FIG. 3, the third bank layer BN3 may cover the display area DA and may expose a part of the display area DA. An opening may be formed in the area that may be exposed without being covered by the third bank layer BN3, and the pixel defining layer PDL and the light emitting elements ED1, ED2, and ED3 may be disposed in each opening. The light emitting elements ED1, ED2, and ED3 may be disposed at the center of the opening, and the pixel defining layer PDL may be disposed along the outer peripheries of the light emitting elements ED1, ED2, and ED3. The trace patterns TRP1, TRP2, and TRP3 may be disposed on the third bank layer BN3 along the outer periphery of the area that may be exposed without being covered by the third bank layer BN3. Although it may be illustrated in FIG. 3 that the area that is exposed without being covered by the third bank layer BN3 has a circular shape, the area may have a polygonal shape such as a triangle, a quadrangle, or a hexagon, and the shape of the trace patterns TRP1, TRP2, and TRP3 disposed at the outer periphery of the exposed area may also be changed. The trace patterns TRP1, TRP2, and TRP3 may be disposed at a level higher than that of the third bank layer BN3, and the pixel defining layer PDL and the light emitting elements ED1, ED2, and ED3 may be disposed at a level lower than that of the third bank layer BN3.

The areas that may be exposed without being covered by the third bank layer BN3 may be spaced apart from each other in the first direction DR1, and may also be spaced apart from each other in the second direction DR2. The shape and arrangement of the areas that may be exposed without being covered by the third bank layer BN3 may not be limited to those shown in FIG. 3, and such areas may be arranged in a PENTILE™ type.

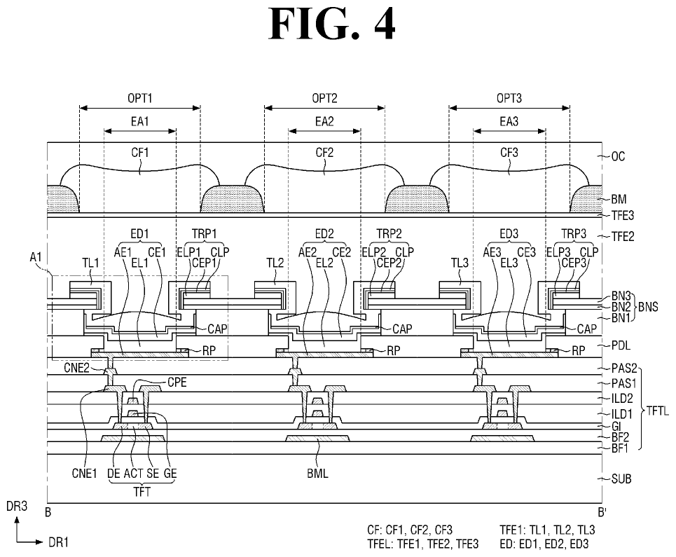

FIG. 4 is a schematic cross-sectional view illustrating a part of a display device according to an embodiment. Specifically, FIG. 4 is a schematic cross-sectional view taken along line B-B′ of FIG. 3, and also illustrates an organic encapsulation layer TFE2, a second inorganic encapsulation layer TFE3, color filters CF that includes CF1, CF2, and CF3, a light blocking layer BM, and an overcoat layer OC that may be disposed above the components shown in the plan view of FIG. 3. FIG. 4 illustrates the schematic cross section of the substrate SUB, the thin film transistor layer TFTL, the light emitting element layer EML, the thin film encapsulation layer TFEL, and the color filter layer CFL.

The thin film transistor layer TFTL may include a first buffer layer BF1, a lower metal layer BML, a second buffer layer BF2, a thin film transistor TFT, a gate insulating layer GI, a first interlayer insulating layer ILD1, a capacitor electrode CPE, a second interlayer insulating layer ILD2, a first connection electrode CNE1, a first passivation layer PAS1, a second connection electrode CNE2, and a second passivation layer PAS2.

The first buffer layer BF1 may be disposed on the substrate SUB. The first buffer layer BF1 may include an inorganic layer capable of preventing penetration of air or moisture. For example, the first buffer layer BF1 may include multiple inorganic layers alternately stacked on each other.

The lower metal layer BML may be disposed on the first buffer layer BF1. For example, the lower metal layer BML may be formed as a single layer or multiple layers made of any one of molybdenum (Mo), aluminum (Al), chromium (Cr), gold (Au), titanium (Ti), nickel (Ni), neodymium (Nd) and copper (Cu), an alloy thereof, or a combination thereof.

The second buffer layer BF2 may cover the first buffer layer BF1 and the lower metal layer BML. The second buffer layer BF2 may include an inorganic layer capable of preventing penetration of air or moisture. For example, the second buffer layer BF2 may include multiple inorganic layers alternately stacked on each other.

The thin film transistor TFT may be disposed on the second buffer layer BF2, and may constitute a pixel circuit of each of multiple pixels. For example, the thin film transistor TFT may be a switching transistor or a driving transistor of the pixel circuit. The thin film transistor TFT may include a semiconductor layer ACT, a source electrode SE, a drain electrode DE, and a gate electrode GE.

The semiconductor layer ACT may be disposed on the second buffer layer BF2. The semiconductor layer ACT may overlap the lower metal layer BML and the gate electrode GE in a thickness direction DR3, and may be insulated from the gate electrode GE by the gate insulating layer GI. In a part of the semiconductor layer ACT, a material of the semiconductor layer ACT may be made into a conductor to form the source electrode SE and the drain electrode DE.

The gate electrode GE may be disposed on the gate insulating layer GI. The gate electrode GE may overlap the semiconductor layer ACT in the thickness direction DR3 with the gate insulating layer GI disposed therebetween.

The gate insulating layer GI may be disposed on the semiconductor layer ACT. For example, the gate insulating layer GI may cover the semiconductor layer ACT and the second buffer layer BF to insulate the gate electrode GE from the semiconductor layer ACT. The gate insulating layer GI may include a contact hole through which the first connection electrode CNE1 passes.

The first interlayer insulating layer ILD1 may cover the gate electrode GE and the gate insulating layer GI. The first interlayer insulating layer ILD1 may include a contact hole through which the first connection electrode CNE1 passes. The contact hole of the first interlayer insulating layer ILD1 may extend to the contact hole of the gate insulating layer GI and the contact hole of the second interlayer insulating layer ILD2.

The capacitor electrode CPE may be disposed on the first interlayer insulating layer ILD1. The capacitor electrode CPE may overlap the gate electrode GE in the thickness direction DR3. The capacitor electrode CPE and the gate electrode GE may form a capacitor.

The second interlayer insulating layer ILD2 may cover the capacitor electrode CPE and the first interlayer insulating layer ILD1. The second interlayer insulating layer ILD2 may include a contact hole through which the first connection electrode CNE1 passes. The contact hole of the second interlayer insulating layer ILD2 may extend to the contact hole of the first interlayer insulating layer ILD1 and the contact hole of the gate insulating layer GI.

The first connection electrode CNE1 may be disposed on the second interlayer insulating layer ILD2. The first connection electrode CNE1 may electrically connect the drain electrode DE of the thin film transistor TFT to the second connection electrode CNE2. The first connection electrode CNE1 may be inserted into a contact hole provided in the second interlayer insulating layer ILD2, the first interlayer insulating layer ILD1, and the gate insulating layer GI to be in contact with the drain electrode DE of the thin film transistor TFT.

The first passivation layer PAS1 may cover the first connection electrode CNE1 and the second interlayer insulating layer ILD2. The first passivation layer PAS1 may protect the thin film transistor TFT. The first passivation layer PAS1 may include a contact hole through which the second connection electrode CNE2 passes.

The second connection electrode CNE2 may be disposed on the first passivation layer PAS1. The second connection electrode CNE2 may electrically connect the first connection electrode CNE1 to pixel electrodes AE1, AE2, and AE3 of the light emitting element ED. The second connection electrode CNE2 may be inserted into a contact hole formed in the first passivation layer PAS1 to be in contact with the first connection electrode CNE1.

The second passivation layer PAS2 may cover the second connection electrode CNE2 and the first passivation layer PAS1. The second passivation layer PAS2 may include a contact hole through which the pixel electrodes AE1, AE2, and AE3 of the light emitting element ED pass.

The light emitting element layer EML may be disposed on the thin film transistor layer TFTL. The light emitting element layer EML may include the light emitting element ED, the pixel defining layer PDL, a capping layer CAP, and a bank structure BNS. The light emitting element ED may include the pixel electrodes AE1, AE2, and AE3, light emitting layers EL1, EL2, and EL3, and common electrodes CE1, CE2, and CE3.

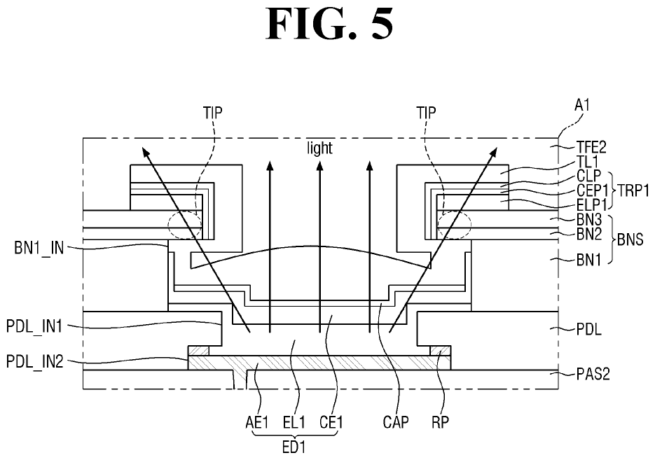

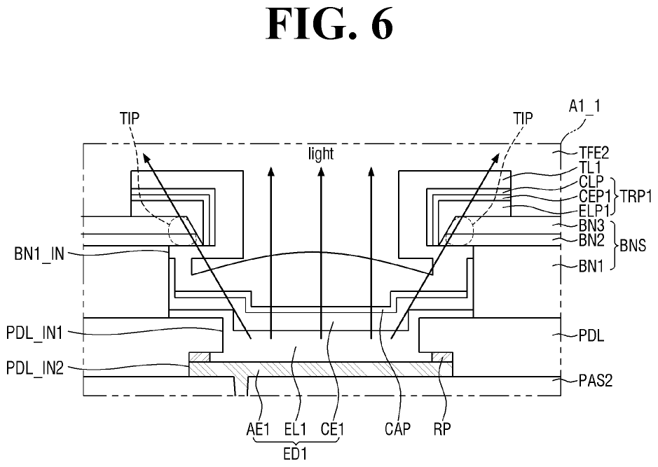

FIG. 5 is an enlarged view showing a first emission area of FIG. 4, specifically, area A1. FIG. 6 is an enlarged view showing a first emission area according to an embodiment, specifically area A1_1.

Referring to FIGS. 5 and 6 in addition to FIG. 4, the display device 10 may include multiple emission areas EA1, EA2, and EA3 disposed in the display area DA. The emission areas EA1, EA2, and EA3 may include an area where light may be emitted from the light emitting elements ED1, ED2, and ED3 and passes through the color filter layer CFL in the third direction DR3. The emission areas EA1, EA2, and EA3 may include a first emission area EA1, a second emission area EA2, and a third emission area EA3 spaced apart from each other and emitting light of the same or different colors.

In an embodiment, the areas or sizes of the first to third emission areas EA1, EA2, and EA3 may be the same. For example, in the display device 10, the first emission area EA1, the second emission area EA2, and the third emission area EA3 may have the same area. However, the disclosure may not be limited thereto. In the display device 10, the areas or sizes of the first to third emission areas EA1, EA2, and EA3 may be different from each other. For example, the areas of the second emission area EA2 may be greater than the areas of the first emission area EA1 and the third emission area EA3, and the area of the third emission area EA3 may be greater than the area of the first emission area EA1. The intensity of light emitted from the corresponding emission areas EA1, EA2, and EA3 may vary according to the areas of the emission areas EA1, EA2, and EA3, and the areas of the emission areas EA1, EA2, and EA3 may be adjusted to control the color of the screen displayed on the display device 10. Although it may be illustrated in the embodiment of FIG. 4 that the emission areas EA1, EA2, and EA3 have the same area, the disclosure may not be limited thereto.

In the display device 10, a first emission area EA1, a second emission area EA2, and a third emission area EA3 disposed adjacent to each other may form a pixel group. A pixel group may include the emission areas EA1, EA2, and EA3 emitting light of different colors to express a white gray scale. However, the disclosure may not be limited thereto, and the combination of the emission areas EA1, EA2, and EA3 constituting a pixel group may be variously modified depending on the arrangement of the emission areas EA1, EA2, and EA3, the color of the light emitted from the emission areas EA1, EA2, and EA3, and the like.

Multiple openings formed in the bank structure BNS of the light emitting element layer EML may be defined along the boundary of the bank structure BNS. First to third bank layers BN1, BN2, and BN3 of the bank structure BNS may surround the emission areas EA1, EA2, and EA3. The opening may include first to third emission areas EA1, EA2, and EA3.

The display device 10 may include the light emitting elements ED1, ED2, and ED3 disposed in the different emission areas EA1, EA2, and EA3. The light emitting elements ED1, ED2, and ED3 may include a first light emitting element ED1 disposed in the first emission area EA1, a second light emitting element ED2 disposed in the second emission area EA2, and a third light emitting element ED3 disposed in the third emission area EA3.

The light emitting elements ED1, ED2, and ED3 may include the pixel electrodes AE1, AE2, and AE3, the light emitting layers EL1, EL2, and EL3, and the common electrodes CE1, CE2, and CE3, respectively, and the light emitting layers EL1, EL2, and EL3 disposed in the different emission areas EA1, EA2, and EA3 may emit light of different colors depending on the materials of the light emitting layers EL1, EL2, and EL3. For example, the first light emitting element ED1 disposed in the first emission area EA1 may emit first light of a red color having a peak wavelength within a range of about 610 nm to about 650 nm, the second light emitting element ED2 disposed in the second emission area EA2 may emit second light of a green color having a peak wavelength within a range of about 510 nm to about 550 nm, and the third light emitting element ED3 disposed in the third emission area EA3 may emit third light of a blue color having a peak wavelength within a range of about 440 nm to about 480 nm. The first to third emission areas EA1, EA2, and EA3 constituting a pixel may respectively include the light emitting elements ED1, ED2, and ED3 emitting lights of different colors to express a white gray scale. The light emitting layers EL1, EL2, and EL3 may include two or more materials emitting light of different colors, so that a light emitting layer may emit mixed light. For example, the light emitting layers EL1, EL2, and EL3 may include a red light emitting material and a green light emitting material to emit yellow light, or may include the red light emitting material, the green light emitting material, and a blue light emitting material to emit white light.

The pixel electrodes AE1, AE2, and AE3 may be disposed on the second passivation layer PAS2. The pixel electrodes AE1, AE2, and AE3 may be disposed in the emission areas EA1, EA2, and EA3, respectively. The pixel electrodes AE1, AE2, and AE3 may include a first pixel electrode AE1 disposed in the first emission area EA1, a second pixel electrode AE2 disposed in the second emission area EA2, and a third pixel electrode AE3 disposed in the third emission area EA3. The first pixel electrode AE1, the second pixel electrode AE2, and the third pixel electrode AE3 may be disposed to be spaced apart from each other on the second passivation layer PAS2. Although it may be illustrated in FIG. 4 that the first to third pixel electrodes AE1, AE2, and AE3 may be spaced apart from each other in the first direction DR1, the disclosure may not be limited thereto, and they may be spaced apart from each other in any direction in the plane formed by the first direction DR1 and the second direction DR2.

The pixel electrodes AE1, AE2, and AE3 may be electrically connected to the drain electrode DE of the thin film transistor TFT through the first and second connection electrodes CNE1 and CNE2. The edges of the pixel electrodes AE1, AE2, and AE3 spaced apart from each other may be covered by the pixel defining layer PDL, so that the first to third pixel electrodes AE1, AE2, and AE3 may be insulated from each other.

The pixel electrodes AE1, AE2, and AE3 may include a transparent electrode material or/and a conductive metal material. The metal material may be at least one of silver (Ag), copper (Cu), aluminum (Al), nickel (Ni), lanthanum (La), titanium (Ti), and titanium nitride (TiN). The transparent electrode material may be at least one of indium tin oxide (ITO), indium zinc oxide (IZO), and indium tin zinc oxide (ITZO). The pixel electrodes AE1, AE2, and AE3 may have a multilayer structure of a transparent electrode material and a conductive metal material.

The pixel defining layer PDL may be disposed on the second passivation layer PAS2, a residual pattern RP, and the pixel electrodes AE1, AE2, and AE3. The pixel defining layer PDL may be disposed on the entire second passivation layer PAS2, and may cover the side surfaces of the pixel electrodes AE1, AE2, and AE3 and the residual pattern RP to partially expose the top surfaces of the pixel electrodes AE1, AE2, and AE3. For example, the pixel defining layer PDL may expose the first pixel electrode AE1 in the first emission area EA1, and the first light emitting layer EL1 may be disposed (e.g., directly disposed) on the first pixel electrode AE1. The pixel defining layer PDL may include a protruding portion that overlaps the pixel electrodes AE1, AE2, and AE3 in the thickness direction DR3, and a body portion that does not overlap the pixel electrodes AE1, AE2, and AE3.

The pixel defining layer PDL may include an inorganic insulating material. The pixel defining layer PDL may include at least one of a silicon nitride layer, a silicon oxynitride layer, a silicon oxide layer, a titanium oxide layer, an aluminum oxide layer, tantalum oxide, hafnium oxide, zinc oxide, and an amorphous silicon layer, but the disclosure may not be limited thereto.

In accordance with an embodiment, the pixel defining layer PDL may be disposed on the pixel electrodes AE1, AE2, and AE3, and may be spaced apart from the top surfaces of the pixel electrodes AE1, AE2, and AE3. The protruding portion of the pixel defining layer PDL may not be in direct contact with the top surfaces of the pixel electrodes AE1, AE2, and AE3 while overlapping them in the thickness direction DR3, and a part of light emitting layers EL1, EL2, and EL3 of the light emitting elements ED1, ED2, and ED3 and/or the residual pattern RP may be disposed between the pixel defining layer PDL and the pixel electrodes AE1, AE2, and AE3. However, the pixel defining layer PDL may be in direct contact with the side surfaces of the pixel electrodes AE1, AE2, and AE3. The side surface PDL_IN1 of the protruding portion of the pixel defining layer PDL may protrude toward (e.g., towards a center of) the emission areas EA1, EA2, and EA3 more than the side surface of the third bank layer BN3.

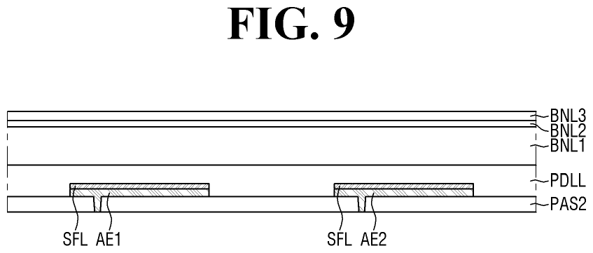

The residual pattern RP may be disposed on the edge of each of the pixel electrodes AE1, AE2, and AE3. The pixel defining layer PDL may not be in direct contact with the top surfaces of the pixel electrodes AE1, AE2, and AE3 due to the residual pattern RP. The residual pattern RP may be formed by removing a part of a sacrificial layer SFL (see FIG. 9) disposed on the pixel electrodes AE1, AE2, and AE3 in the fabrication process of the display device 10. The residual pattern RP may include an oxide semiconductor. For example, the residual pattern RP may include an oxide semiconductor or transparent conductive oxide (TCO). In an embodiment, the residual pattern RP may include zinc (Zn), and specifically, may include at least one of zinc-indium-tin oxide (ZITO), indium-gallium-zinc oxide (IGZO), indium-tin oxide (IZO), and zinc-tin oxide (ZTO). The residual pattern RP may include a first (or inner) side surface facing the emission areas EA1, EA2, and EA3 and a second (or outer) side surface that may be the opposite surface thereof, and the first side surface may be recessed compared to the side surface PDL_IN1 of the protruding portion of the pixel defining layer PDL as shown in FIGS. 5 and 6. Although not shown in the drawing, the first side surface of the residual pattern RP may be aligned with the side surface PDL_IN1 of the protruding portion of the pixel defining layer PDL, or may protrude toward the emission areas EA1, EA2, and EA3 more than the side surface of the protruding portion of the pixel defining layer PDL. The second side surface of the residual pattern RP may be in contact with the side surface of the body portion of the pixel defining layer PDL.

The light emitting layers EL1, EL2, and EL3 may be disposed on the pixel electrodes AE1, AE2, and AE3, respectively. The light emitting layers EL1, EL2, and EL3 may be organic light emitting layers made of an organic material, and may be formed on the pixel electrodes AE1, AE2, and AE3, respectively by a deposition process. In case that the thin film transistor TFT applies a voltage (e.g., predetermined or selectable voltage) to the pixel electrodes AE1, AE2, and AE3 of the light emitting elements ED1, ED2, and ED3, and the common electrodes CE1, CE2, and CE3 of the light emitting elements ED1, ED2, and ED3 receive a common voltage or a cathode voltage, holes and electrons may be transferred to the light emitting layers EL1, EL2, and EL3 through the hole transporting layer and the electron transporting layer, respectively, and may be combined with each other to emit light in the light emitting layers EL1, EL2, and EL3.

The light emitting layers EL1, EL2, and EL3 may include the first light emitting layer EL1, the second light emitting layer EL2, and the third light emitting layer EL3 disposed in the different emission areas EA1, EA2, and EA3. The first light emitting layer EL1 may be disposed on the first pixel electrode AE1 in the first emission area EA1, the second light emitting layer EL2 may be disposed on the second pixel electrode AE2 in the second emission area EA2, and the third light emitting layer EL3 may be disposed on the third pixel electrode AE3 in the third emission area EA3. The light emitting layers EL1, EL2, and EL3 may emit light of different colors, or a light emitting layer may emit mixed light. In an embodiment, the first light emitting layer EL1 may emit red light, the second light emitting layer EL2 may emit green light, and the third light emitting layer EL3 may emit blue light. In an embodiment, the first light emitting layer EL1 may emit yellow light that may be mixed light of red light and green light, and the second light emitting layer EL2 may emit blue light. In an embodiment, the first light emitting layer EL1 may emit white light that may be mixed light of red light, green light, and blue light.

The light emitting layers EL1, EL2, and EL3 may be disposed on the top surface of the pixel defining layer PDL. The light emitting layers EL1, EL2, and EL3 may be disposed in the space between the pixel electrodes AE1, AE2, and AE3 and the pixel defining layer PDL. The light emitting layers EL1, EL2, and EL3 may be in contact with the pixel defining layer PDL, the residual pattern RP, and the pixel electrodes AE1, AE2, and AE3.

The common electrodes CE1, CE2, and CE3 may be disposed on the light emitting layers EL1, EL2, and EL3, respectively. The common electrodes CE1, CE2, and CE3 may include a transparent conductive material, so that the light generated in the light emitting layers EL1, EL2, and EL3 may be emitted. The common electrodes CE1, CE2, and CE3 may receive a common voltage or a low potential voltage. In case that the pixel electrodes AE1, AE2, and AE3 receive the voltage corresponding to a data voltage and the common electrodes CE1, CE2, and CE3 receive the low potential voltage, a potential difference may be formed between the pixel electrodes AE1, AE2, and AE3 and the common electrodes CE1, CE2, and CE3, so that the light emitting layers EL1, EL2, and EL3 may emit light.

The common electrodes CE1, CE2, and CE3 may include the first common electrode CE1, the second common electrode CE2, and the third common electrode CE3 disposed in the different emission areas EA1, EA2, and EA3 respectively. The first common electrode CE1 may be disposed on the first light emitting layer EL1 in the first emission area EA1, the second common electrode CE2 may be disposed on the second light emitting layer EL2 in the second emission area EA2, and the third common electrode CE3 may be disposed on the third light emitting layer EL3 in the third emission area EA3. The first to third common electrodes CE1, CE2, and CE3 may be spaced apart from each other.

The capping layer CAP may be disposed on the common electrodes CE1, CE2, and CE3. The capping layer CAP may include an organic or inorganic insulating material to cover patterns disposed on the light emitting elements ED1, ED2, and ED3. The capping layer CAP may prevent the light emitting elements ED1, ED2, and ED3 from being damaged by external air. In an embodiment, the capping layer CAP may include an organic material such as a-NPD, NPB, TPD, m-MTDATA, Alq₃, LiF, and/or CuPc, or an inorganic material such as aluminum oxide, titanium oxide, tantalum oxide, hafnium oxide, zinc oxide, silicon oxide, silicon nitride, and/or silicon oxynitride.

The display device 10 may include the bank structures BNS disposed on the pixel defining layer PDL. The bank structure BNS may have a structure in which the bank layers BN1 and BN2 including different materials may be sequentially stacked on each other, may include the openings including the emission areas EA1, EA2, and EA3, and may be disposed to overlap the light blocking layer BM to be described later. The light emitting elements ED1, ED2, and ED3 of the display device 10 may be disposed to overlap the openings of the bank structure BNS.

The bank structure BNS may include the first bank layer BN1, the second bank layer BN2, and the third bank layer BN3 that may be sequentially stacked on each other on the pixel defining layer PDL.

The first bank layer BN1 may be disposed on the pixel defining layer PDL. The side surface BN1_IN of the first bank layer BN1 may be recessed more than the side surface PDL_IN1 of the pixel defining layer PDL in a direction opposite to the direction facing the centers of the emission areas EA1, EA2, and EA3 in a plan view. The side surface BN1_IN1 of the first bank layer BN1 may be recessed more than the side surface of the second bank layer BN2 to be described later in a direction opposite to a direction facing the emission areas EA1, EA2, and EA3.

In accordance with an embodiment, the first bank layer BN1 may include a metal material. The first bank layer BN1 may include an opaque metal. In an embodiment, the first bank layer BN1 may include aluminum (Al).

In an embodiment, the thickness of the first bank layer BN1 may be within a range of about 4000 Å to about 7000 Å. In case that the above range is satisfied, it is possible to form the light emitting layers EL1, EL2, and EL3 and the common electrodes CE1, CE2, and CE3 that may be spaced apart from each other by a deposition and etching process instead of a mask process.

In accordance with an embodiment, the common electrodes CE1, CE2, and CE3 may be in contact (e.g., direct contact) with the side surface BNL_IN of the first bank layer BN1. The common electrodes CE1, CE2, and CE3 of the different light emitting elements ED1, ED2, and ED3 may be in contact (e.g., direct contact) with the first bank layer BN1, the first bank layer BN1 may include a metal material, and the common electrodes CE1, CE2, and CE3 may be electrically connected to each other through the first bank layer BN1.

The light emitting layers EL1, EL2, and EL3 may be in contact (e.g., direct contact) with the side surface BN1_IN of the first bank layer BN1. The contact area between the common electrodes CE1, CE2, and CE3 and the side surface BN1_IN of the first bank layer BN1 may be greater than the contact area between the light emitting layers EL1, EL2, and EL3 and the side surface BN1_IN of the first bank layer BN1. The common electrodes CE1, CE2, and CE3 may be disposed in larger areas on the side surface BN1_IN of the first bank layer BN1 compared to the light emitting layers EL1, EL2, and EL3, or may be disposed at higher positions on the side surface BN1_IN of the first bank layer BN1 compared to the light emitting layers EL1, EL2, and EL3. Since the common electrodes CE1, CE2, and CE3 of the different light emitting elements ED1, ED2, and ED3 may be electrically connected to each other through the first bank layer BN1, it may be advantageous that they are in contact with the first bank layer BN1 in larger areas.

The second bank layer BN2 may be disposed on the first bank layer BN1. The second bank layer BN2 may include a tip TIP that may be an area protruding compared to the first bank layer BN1. The side surface of the second bank layer BN2 may protrude toward the centers of emission areas EA1, EA2, and EA3 more than the side surface BN1_IN of the first bank layer BN1.

The third bank layer BN3 may be disposed on the second bank layer BN2. The third bank layer BN3 may include the tip TIP that may be an area protruding compared to the first bank layer BN1. The side surface of the third bank layer BN3 may protrude toward the centers of emission areas EA1, EA2, and EA3 more than the side surface BN1_IN of the first bank layer BN1.

The side surface of the second bank layer BN2 and the side surface of the third bank layer BN3 may be aligned with each other in a plan view. The side surface of the second bank layer BN2 and the side surface of the third bank layer BN3 may be aligned to form an approximately flat surface in the direction DR3 perpendicular to the substrate SUB (see FIG. 5), or to form an approximately flat surface in an inclined direction (see FIG. 6). The disclosure may not be limited thereto, and the side surface of the second bank layer BN2 and the side surface of the third bank layer BN3 may not be aligned.

Since the side surfaces of the second and third bank layers BN2 and BN3 have a shape protruding toward centers of the emission areas EA1, EA2 and EA3 more than the side surface BN1_IN of the first bank layer BN1, an undercut structure of the first bank layer BN1 may be formed under the tips TIP of the second and third bank layers BN2 and BN3. The second and third bank layers BN2 and BN3 may include the tips TIP, so that the separated or spaced apart light emitting elements ED1, ED2, and ED3 may be formed without a mask process.

In the display device 10 according to an embodiment, the bank structure BNS may include the tips TIP protruding toward centers of the emission areas EA1, EA2, and EA3, and thus may be formed by the deposition and etching process instead of the mask process. Further, it may be possible to individually form different layers in different emission areas EA1, EA2, and EA3 by the deposition process. For example, even in case that the light emitting layers EL1, EL2, and EL3 of the light emitting elements ED1, ED2, and ED3 and the common electrodes CE1, CE2, and CE3 may be formed by a deposition process using no mask, the deposited materials may be disconnected with the bank structure BNS disposed therebetween by the tips TIP of the second and third bank layers BN2 and BN3 without being connected between the emission areas EA1, EA2, and EA3. By a process of forming a material for forming a specific layer on the entire surface of the display device 10 and then removing the layer formed in an undesired region by etching, it may be possible to individually form different layers in the different emission areas EA1, EA2, and EA3. In the display device 10, the different light emitting elements ED1, ED2, and ED3 may be formed in the different emission areas EA1, EA2, and EA3 by the deposition and etching process without using the mask process, and an unnecessary component in the display device 10 may be omitted to minimize the area of the non-display area NDA.

The side surface shape of the bank structure BNS may be a structure formed by a difference in etch rates in an etching process due to different materials of the first to third bank layers BN1, BN2, and BN3. In accordance with an embodiment, the second and third bank layers BN2 and BN3 may include a material having an etch rate lower than that of the first bank layer BN1, and the first bank layer BN1 may be further etched during the etching process to form the undercut under the tips TIP of the second and third bank layers BN2 and BN3. In an embodiment, the first bank layer BN1 may include aluminum (Al), and the second and third bank layers BN2 and BN3 may include a transparent conductive oxide (TCO).

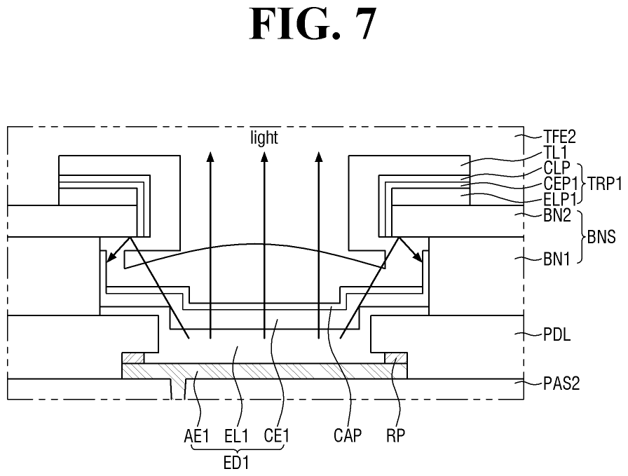

In case that the second bank layer BN2 disposed on the first bank layer BN1 may be made of an opaque material such as titanium (Ti), a part of the light emitted from the light emitting elements ED1, ED2, and ED3 may be reflected by the tip TIP of the second bank layer BN2 as illustrated in FIG. 7 and become extinct. Further, the opaque second bank layer BN2 becomes a dead space in the display device.

On the other hand, in case that the second and third bank layers BN2 and BN3 may be made of an amorphous transparent material as illustrated in FIGS. 5 and 6, the light emitted from the light emitting elements ED1, ED2 and ED3 may pass through the second and third bank layers BN2 and BN3. The light efficiency may be increased and the dead space may be reduced, so that the pixel gap may be narrowed. The transmittance of the second and third bank layers BN2 and BN3 for visible light (i.e., wavelengths in a range of about 380 nm to about 780 nm) may be about 85% or more or about 89% or more. The transparent material that may be used for the second and third bank layers BN2 and BN3 may be a transparent conductive oxide (TCO), and may include indium tin oxide (ITO), indium zinc oxide (IZO), indium tin zinc oxide (ITZO), zinc-indium-tin oxide (ZITO), indium-gallium-zinc oxide (IGZO), indium-tin oxide (IZO), zinc-tin oxide (ZTO), or a combination thereof. The transparent conductive oxide (TCO) has excellent adhesion with the first inorganic encapsulation layer TFE1, and thus may prevent permeation of moisture from outside air.

The second bank layer BN2 may include zinc (Zn). In an embodiment, the second bank layer BN2 may include at least one of zinc-indium-tin oxide (ZITO), indium-gallium-zinc oxide (IGZO), indium-tin oxide (IZO), or zinc-tin oxide (ZTO). The bottom surface of the tip TIP of the second bank layer BN2 may be continuously exposed and damaged in the etching process, so that the tip TIP may be bent. In case that the second bank layer BN2 includes zinc (Zn), it may not be etched by a fluorine-based gas, so that the tip TIP may maintain its shape without being damaged. Therefore, the second bank layer BN2 adjacent to the first emission area EA1, the second bank layer BN2 adjacent to the second emission area EA2, and the second bank layer BN2 adjacent to the third emission area EA3 may have the same thickness.

In accordance with an embodiment, the ratio of zinc (Zn) contained in the second bank layer BN2 may be in a range of about 5 at % to about 50 at % with respect to the total number of atoms. In case that the ratio of zinc (Zn) may be within the above range, a potential difference may be reduced, and thus corrosion between the first bank layer BN1 and the third bank layer BN3 may be prevented.

The third bank layer BN3 may include hydrogen. The third bank layer BN3 may be made of an amorphous material including hydrogen between atoms of a transparent conductive oxide (TCO). In case that hydrogen gas may be additionally included in argon gas in the sputtering process of the transparent conductive oxide (TCO), hydrogen may be located between atoms of the transparent conductive oxide (TCO). In an embodiment, the third bank layer BN3 may include hydrogen and indium tin oxide (ITO). In case that the concentration of hydrogen gas used in the sputtering process increases, the ratio of hydrogen contained in the third bank layer BN3 may increase, and in case that the concentration of hydrogen gas decreases, the ratio of hydrogen contained in the third bank layer BN3 may decrease.

The thickness of the third bank layer BN3 may be greater than that of the second bank layer BN2. In an embodiment, the third bank layer BN3 may have a thickness in a range of about 400 Å to about 1000 Å. In case that only a transparent conductive oxide (TCO) is included, there may be a limit in increasing the thickness while maintaining amorphous characteristics, but the thickness may be increased in case that both a transparent conductive oxide (TCO) and hydrogen are included.

The sum of the thickness of the second bank layer BN2 and the thickness of the third bank layer BN3 may be in a range of about 500 Å to about 1500 Å. The thickness of the first bank layer BN1 may be considerably greater than those of the second and third bank layers BN2 and BN3. The thickness of the first bank layer BN1 may be greater than the sum of the thickness of the second bank layer BN2 and the thickness of the third bank layer BN3. The thickness of the first bank layer BN1 may be more than about three times the sum of the thickness of the second bank layer BN2 and the thickness of the third bank layer BN3. In case that the above range is satisfied, the light emitting layers EL1, EL2, and EL3 and the common electrodes CE1, CE2, and CE3 may be smoothly spaced apart (or separated) from the trace patterns TRP1, TRP2, and TRP3 while ensuring the thin tip TIP.

The tips TIP of the second and third bank layers BN2 and BN3 may overlap the common electrodes CE1, CE2, and CE3 in the direction DR3 perpendicular to the substrate SUB. Further, the tips TIP of the second and third bank layers BN2 and BN3 may overlap the light emitting layers EL1, EL2, and EL3 in the direction DR3 perpendicular to the substrate SUB. Further, the tips TIP of the second and third bank layers BN2 and BN3 may overlap the pixel defining layer PDL in the direction DR3 perpendicular to the substrate SUB. The common electrodes CE1, CE2, and CE3 may be formed under the bottom surface of the tip TIP of the second bank layer BN2. The maximum distance from the substrate SUB to the common electrodes CE1, CE2, and CE3 may be smaller than the maximum distance from the substrate SUB to the second bank layer BN2.

The display device 10 may include the trace patterns TRP1, TRP2, and TRP3 that may be traces of the deposition process on the bank structure BNS. The trace patterns TRP1, TRP2, and TRP3 may include organic patterns ELP1, ELP2, and ELP3, electrode patterns CEP1, CEP2, and CEP3, and a capping pattern CLP, and may surround the outer peripheries of the emission areas EA1, EA2, and EA3 on the third bank layer BN3.

The trace patterns TRP1, TRP2, and TRP3 may be traces formed because they may be disconnected without being electrically connected with the light emitting layers EL1, EL2, and EL3, the common electrodes CE1, CE2, CE3, and the capping layer CAP in the emission areas EA1, EA2, and EA3 due to the tip TIP of the bank structure BNS. The light emitting layers EL1, EL2, and EL3, the common electrodes CE1, CE2, and CE3, and the capping layer CAP may be formed in the openings, and the organic patterns ELP1, ELP2, and ELP3 and the light emitting layers EL1, EL2, and EL3 may be electrically disconnected from each other, the electrode patterns CEP1, CEP2, and CEP3 and the common electrodes CE1, CE2, and CE3 may be electrically disconnected from each other, and the capping pattern CLP and the capping layer CAP may be electrically disconnected from each other by the tip TIP of the bank structure BNS. The trace patterns TRP1, TRP2, and TRP3 may be formed by patterning them near the emission areas EA1, EA2, and EA3 or the opening.

The display device 10 according to an embodiment may include the organic patterns ELP1, ELP2, and ELP3 and the light emitting layers EL1, EL2, and EL3 including a same material, the organic patterns ELP1, ELP2, and ELP3 being disposed on the bank structure BNS. Since the light emitting layers EL1, EL2, and EL3 may be formed by a process of depositing a material on the entire surface of the display device 10, the materials forming the light emitting layers EL1, EL2, and EL3 may also be deposited on the bank structure BNS in addition to the emission areas EA1, EA2, and EA3.

For example, the display device 10 may include the organic patterns ELP1, ELP2, and ELP3 disposed on the bank structure BNS. The organic patterns ELP1, ELP2, and ELP3 may include the first organic pattern ELP1, the second organic pattern ELP2, and the third organic pattern ELP3 disposed on the third bank layer BN3 of the bank structure BNS.

The first organic pattern ELP1 and the first light emitting layer EL1 of the first light emitting element ED1 may include a same material. The second organic pattern ELP2 and the second light emitting layer EL2 of the second light emitting element ED2 may include a same material, and the third organic pattern ELP3 and the third light emitting layer EL3 of the third light emitting element ED3 may include a same material. The organic patterns ELP1, ELP2, and ELP3 may be formed in the process of forming the light emitting layers EL1, EL2, and EL3 including a same material as those of the organic patterns ELP1, ELP2, and ELP3 respectively. The organic patterns ELP1, ELP2, and ELP3 may be disposed adjacent to the emission areas EA1, EA2, and EA3 where the light emitting layers EL1, EL2, and EL3 may be disposed, respectively.

The display device 10 according to an embodiment may include the electrode patterns CEP1, CEP2, and CEP3 including a same material as those of the common electrodes CE1, CE2, and CE3 respectively and disposed on the bank structure BNS. The first electrode pattern CEP1, the second electrode pattern CEP2, and the third electrode pattern CEP3 may be disposed (e.g., directly disposed) on the first organic pattern ELP1, the second organic pattern ELP2, and the third organic pattern ELP3, respectively. The arrangement relationship of the electrode patterns CEP1, CEP2, and CEP3 and the organic patterns ELP1, ELP2, and ELP3 may be the same as the arrangement relationship of the light emitting layers EL1, EL2, and EL3 of the light emitting elements ED1, ED2, and ED3 and the common electrodes CE1, CE2, and CE3.

The display device 10 may include the capping pattern CLP disposed on the bank structure BNS. The capping pattern CLP may be disposed (e.g., directly disposed) on the first electrode pattern CEP1, the second electrode pattern CEP2, and the third electrode pattern CEP3. The arrangement relationship of the capping pattern CLP and the electrode patterns CEP1, CEP2, and CEP3 may be the same as the arrangement relationship of the common electrodes CE1, CE2, and CE3 of the light emitting elements ED1, ED2, and ED3 and the capping layer CAP.

The thin film encapsulation layer TFEL may be disposed on the light emitting elements ED1, ED2, and ED3 and the bank structure BNS, and may cover the light emitting elements ED1, ED2, and ED3 and the bank structure BNS. The thin film encapsulation layer TFEL may include at least one inorganic layer to prevent oxygen or moisture from permeating into the light emitting element layer EML. The thin film encapsulation layer TFEL may include at least one organic layer to protect the light emitting element layer EML from foreign substances such as dust.

In an embodiment, the thin film encapsulation layer TFEL may include the first inorganic encapsulation layer TFE1, the organic encapsulation layer TFE2, and the second inorganic encapsulation layer TFE3 that may be sequentially stacked on each other.

Each of the first inorganic encapsulation layer TFE1 and the second inorganic encapsulation layer TFE3 may include one or more inorganic insulators. The inorganic insulating material may be any one of silicon oxide, silicon nitride, and silicon oxynitride, and may include, for example, aluminum oxide, titanium oxide, tantalum oxide, hafnium oxide, zinc oxide, silicon oxide, silicon nitride, silicon oxynitride, or a combination thereof v.

The organic encapsulation layer TFE2 may include a polymer-based material. Examples of the polymer-based material may include acrylic resin, epoxy resin, polyimide, polyethylene, the like, or a combination thereof. For example, the organic encapsulation layer TFE2 may include an acrylic resin, for example, polymethyl methacrylate, polyacrylic acid, the like, or a combination thereof. The organic encapsulation layer TFE2 may be formed by curing a monomer or applying a polymer.

The first inorganic encapsulation layer TFE1 may be disposed on the light emitting elements ED1, ED2, and ED3, the trace patterns TRP1, TRP2, and TRP3, and the bank structure BNS. The first inorganic encapsulation layer TFE1 may include a first inorganic layer TL1, a second inorganic layer TL2, and a third inorganic layer TL3 disposed to correspond to the different emission areas EA1, EA2, and EA3, respectively. The first inorganic layer TL1, the second inorganic layer TL2, and the third inorganic layer TL3 may include an inorganic insulating material to cover the light emitting elements ED1, ED2, and ED3, respectively. The first inorganic layer TL1, the second inorganic layer TL2, and the third inorganic layer TL3 may prevent the light emitting elements ED1, ED2, and ED3 from being damaged by external air. The first inorganic layer TL1, the second inorganic layer TL2, and the third inorganic layer TL3 may be disposed to cover the organic patterns ELP1, ELP2, and ELP3, the electrode patterns CEP1, CEP2, and CEP3, and the capping pattern CLP, so that it may be possible to prevent the patterns disposed on the bank structure BNS from being peeled off during the fabrication process of the display device 10.

Since the first inorganic layer TL1, the second inorganic layer TL2, and the third inorganic layer TL3 may be formed by a chemical vapor deposition (CVD) method, they may be formed along the stepped portion of the deposited layers. For example, the first inorganic layer TL1, the second inorganic layer TL2, and the third inorganic layer TL3 may form thin films even under the undercut by the tip TIP of the bank structure BNS.

The first inorganic layer TL1 may be disposed on the first light emitting element ED1 and the first electrode pattern CEP1. The first inorganic layer TL1 may be disposed to cover the first light emitting element ED1, the capping layer CAP, and the second bank layer BN2 along the side surfaces thereof adjacent to the first common electrode CE1, and may also be disposed to cover the organic pattern ELP1, the first electrode pattern CEP1, and the capping pattern CLP. However, the first inorganic layer TL1 may not overlap a second opening and a third opening, and may be disposed only on a first opening and the bank structure BNS around the first opening. Although it may be illustrated in FIGS. 4 to 6 that the first inorganic layer TL1 performs sealing with a non-uniform thickness along the outer surfaces of the first trace pattern TRP1 and the light emitting element ED1, the first inorganic layer TL1 may be disposed with a uniform thickness along the top surface and the side surface of the first trace pattern TRP1, the side surface and the bottom surface of the second bank layer BN2, the side surface of the first bank layer BN1, and the top surface of the first common electrode CE1.

The second inorganic layer TL2 may be disposed on the second light emitting element ED2 and the second electrode pattern CEP2. However, the second inorganic layer TL2 may not overlap the first opening and the third opening, and may be disposed only on the second opening and the bank structure BNS around the second opening.

The third inorganic layer TL3 may be disposed on the third light emitting element ED3 and the third electrode pattern CEP3. However, the third inorganic layer TL3 may not overlap the first opening and the second opening, and may be disposed only on the third opening and the bank structure BNS around the third opening.

The first inorganic layer TL1 may be formed after the first common electrode CE1 may be formed, the second inorganic layer TL2 may be formed after the second common electrode CE2 may be formed, and the third inorganic layer TL3 may be formed after the third common electrode CE3 may be formed. Accordingly, the first to third inorganic layers TL1, TL2, and TL3 may be disposed to cover the different electrode patterns CEP1, CEP2, and CEP3 and the organic patterns ELP1, ELP2, and ELP3, respectively. In the plan view of FIG. 3, the first inorganic layer TL1, the second inorganic layer TL2, and the third inorganic layer TL3 may have the boundary that may be the same as or similar to those of the first to third trace patterns TRP1, TRP2, and TRP3, respectively, and may have areas larger than the area of the opening of the bank structure BNS or the emission areas EA1, EA2, and EA3. The first inorganic layer TL1, the second inorganic layer TL2, and the third inorganic layer TL3 may be spaced apart from each other on the bank structure BNS. Accordingly, a part of the second bank layer BN2 may not overlap the first to third inorganic layers TL1, TL2, and TL3, and a part of the top surface of the second bank layer BN2 may be exposed without being covered by the first to third inorganic layers TL1, TL2, and TL3 in the separation space of the first to third inorganic layers TL1, TL2, and TL3. The exposed top surface of the second bank layer BN2 may be in direct contact with the organic encapsulation layer TFE2 of the thin film encapsulation layer TFEL.

The light blocking layer BM may be disposed on the thin film encapsulation layer TFEL. The light blocking layer BM may include the holes OPT1, OPT2, and OPT3 disposed to overlap the emission areas EA1, EA2, and EA3. For example, the first hole OPT1 may be disposed to overlap the first emission area EA1. The second hole OPT2 may be disposed to overlap the second emission area EA2, and the third hole OPT3 may be disposed to overlap the third emission area EA3. The areas or sizes of the holes OPT1, OPT2, and OPT3 may be larger than the areas or sizes of the emission areas EA1, EA2, and EA3. The holes OPT1, OPT2, and OPT3 of the light blocking layer BM may be formed to be larger than the emission areas EA1, EA2, and EA3, so that the light emitted from the emission areas EA1, EA2, and EA3 may be visually recognized by the user not only from the front surface but also from the side surface of the display device 10.

The light blocking layer BM may include a light absorbing material. For example, the light blocking layer BM may include an inorganic black pigment or an organic black pigment. The inorganic black pigment may be carbon black, and the organic black pigment may include at least one of lactam black, perylene black, or aniline black, but they may not be limited thereto. The light blocking layer BM may prevent visible light infiltration and color mixture between the first to third emission areas EA1, EA2, and EA3, which leads to the improvement of color reproducibility of the display device 10.

The display device 10 may include the color filters CF1, CF2, and CF3 disposed on the emission areas EA1, EA2, and EA3. The color filters CF1, CF2, and CF3 may be disposed to correspond to the emission areas EA1, EA2, and EA3, respectively. For example, the color filters CF1, CF2, and CF3 may be disposed on the light blocking layer BM including the holes OPT1, OPT2, and OPT3 disposed to correspond to the emission areas EA1, EA2, and EA3, respectively. The holes OPT1, OPT2, and OPT3 of the light blocking layer BM may be formed to overlap the emission areas EA1, EA2, and EA3, or the openings of the bank structures BNS, and may form a light exit area from which the light emitted from the emission areas EA1, EA2, and EA3 may be emitted. The color filters CF1, CF2, and CF3 may have areas larger than those of the holes OPT1, OPT2, and OPT3 of the light blocking layer BM, and the color filters CF1, CF2, and CF3 may completely cover the light exit area formed by the holes OPT1, OPT2, and OPT3.

The color filters CF1, CF2, and CF3 may include a first color filter CF1, a second color filter CF2, and a third color filter CF3 disposed to correspond to the different emission areas EA1, EA2, and EA3, respectively. The color filters CF1, CF2, and CF3 may include a colorant such as a dye or a pigment that absorbs light in a wavelength band other than light in a specific wavelength band, and may be disposed to correspond to the color of the light emitted from the emission areas EA1, EA2, and EA3. For example, the first color filter CF1 may be a red color filter that may be disposed to overlap the first emission area EA1 and transmits only the first light of the red color. The second color filter CF2 may be a green color filter that may be disposed to overlap the second emission area EA2 and transmits only the second light of the green color, and the third color filter CF3 may be a blue color filter that may be disposed to overlap the third emission area EA3 and transmits only the third light of the blue color.

The color filters CF1, CF2, and CF3 may be spaced apart from other adjacent color filters CF1, CF2, and CF3 on the light blocking layer BM. The color filters CF1, CF2, and CF3 may have areas larger than those of the holes OPT1, OPT2, and OPT3 of the light blocking layer BM, respectively, while covering the holes, and may have areas enough to be spaced apart from other color filters CF1, CF2, and CF3 on the light blocking layer BM. However, the disclosure may not be limited thereto. The color filters CF1, CF2, and CF3 may be disposed to partially overlap other adjacent color filters CF1, CF2, and CF3. The different color filters CF1, CF2, and CF3 may be areas that do not overlap the emission areas EA1, EA2, and EA3, and may overlap each other on the light blocking layer BM to be described later. In the display device 10, the color filters CF1, CF2, and CF3 may be disposed to overlap each other, so that the intensity of the reflected light by external light may be reduced. Furthermore, the color of the reflected light by the external light may be controlled by adjusting the disposition, shape, and area of the color filters CF1, CF2, and CF3 in a plan view.

The overcoat layer OC may be disposed on the color filters CF1, CF2, and CF3 to planarize the top ends of the color filters CF1, CF2, and CF3. The overcoat layer OC may be a colorless light transmissive layer that does not have a color in a visible light band. For example, the overcoat layer OC may include a colorless light transmissive organic material such as an acrylic resin.

Hereinafter, a fabrication process of the display device 10 according to an embodiment will be described with reference to other drawings.

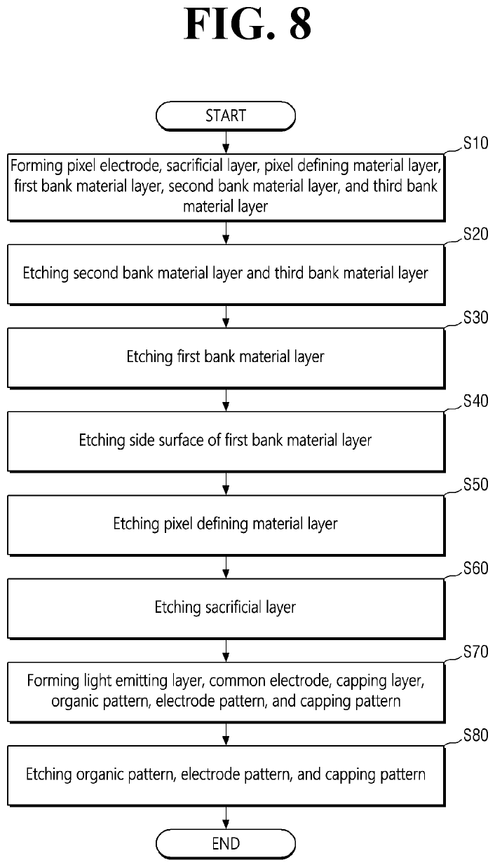

FIG. 8 is a flowchart showing a fabrication process of a display device according to an embodiment, and FIGS. 9 to 18 are detailed schematic cross-sectional views sequentially showing a fabrication process of a display device according to an embodiment.

FIGS. 9 to 18 schematically illustrate a process of forming the light emitting elements ED and the thin film encapsulation layer TFEL, and the bank structure BNS as the light emitting element layer EML of the display device 10. Hereinafter, with respect to the fabrication process of the display device 10, a description of the formation process of each layer will be omitted, and the formation order of each layer will be described.

Referring to FIG. 9, the pixel electrodes AE1, AE2, and AE3 spaced apart from each other, the sacrificial layer SFL, a pixel defining material layer PDLL, and multiple bank material layers BNL1, BNL2 and BNL3 may be formed on the entire second passivation layer PAS2 as per step S10 of FIG. 8.

Although not illustrated in the drawing, the thin film transistor layer TFTL may be disposed on the substrate SUB, and the structure of the thin film transistor layer TFTL may be the same as described above with reference to FIG. 4. A detailed description thereof will be omitted.

In the case of forming the third bank material layer BNL3, a transparent conductive oxide (TCO) may be deposited by a sputtering process. The sputtering process may be performed under a mixed gas atmosphere including hydrogen gas as well as argon gas. Hydrogen gas may be introduced at a flow rate in a range of about 0.1 seem to about 5 sccm.

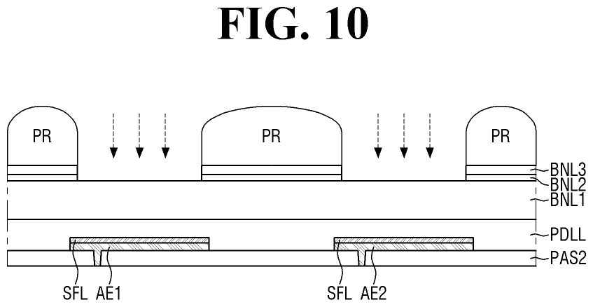

Referring to FIG. 10, a photoresist PR may be formed on the third bank material layer BNL3, and a first etching process (1^{st} etching) for partially etching the second and third bank material layers BNL2 and BNL3 using the photoresist PR as a mask may be performed as per step S20 of FIG. 8. The photoresists PR may be disposed to be spaced apart from each other on the third bank material layer BNL3, and may be disposed to expose areas overlapping the pixel electrodes AE1, AE2, and AE3.

In an embodiment, the first etching process (1^{st} etching) may be performed as wet etching. The second and third bank material layers BNL2 and BNL3 may be anisotropically etched. The second and third bank material layers BNL2 and BNL3 in the area overlapping the pixel electrodes AE1, AE2, and AE3 may be removed, and the first bank material layer BNL1 in the area overlapping the pixel electrodes AE1, AE2, and AE3 may be exposed.

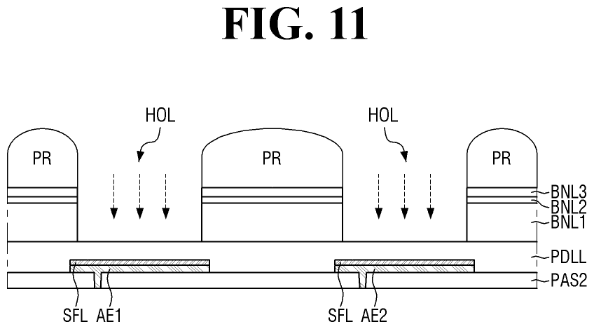

Referring to FIG. 11, the exposed first bank material layer BNL1 may be removed by a second etching process (2^{nd} etching) to form a hole HOL as per step S30 of FIG. 8. In an embodiment, the second etching process may be performed as anisotropic dry etching. The hole HOL may be formed in the area overlapping the pixel electrodes AE1, AE2, and AE3, and the hole HOL may form the opening of the bank structure BNS.

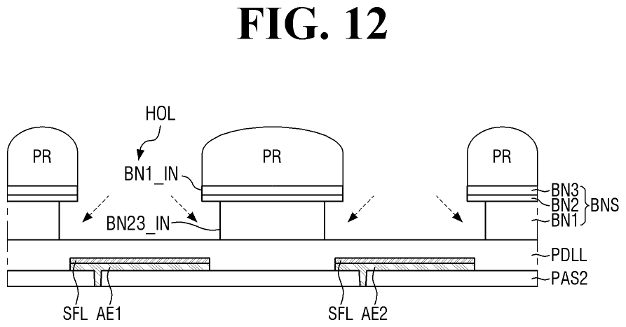

Referring to FIG. 12, the undercut structure of the first bank material layer BNL1 may be formed by a third etching process (3^{rd} etching) as per step S40 of FIG. 8. The etch rate of the first bank material layer BNL1 may be higher than those of the second and third bank material layers BNL2 and BNL3, and the side surfaces BN23_IN of the second and third bank material layers BNL2 and BNL3 may be formed as a structure that protrudes more to a center of the hole HOL than the side surface BN1_IN of the first bank material layer BNL1. The side surfaces BN23_IN of the second and third bank material layers BNL2 and BNL3 may protrude toward the hole HOL more than the side surface BN1_IN of the first bank material layer BNL1 to form the tip TIP, and an undercut may be formed thereunder.

In an embodiment, the third etching process may be isotropic wet etching. The third etching process may use an alkali-based etchant. The bank structure BNS of the first to third bank layers BN1, BN2, and BN3 may be obtained by the third etching process.

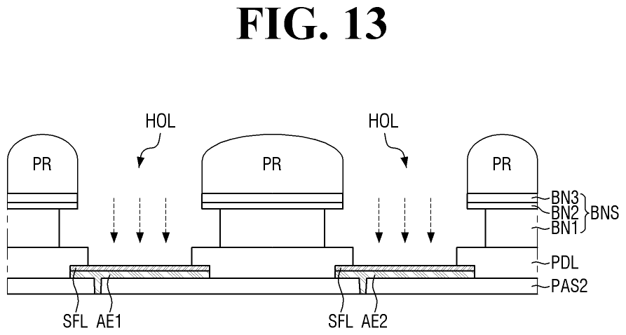

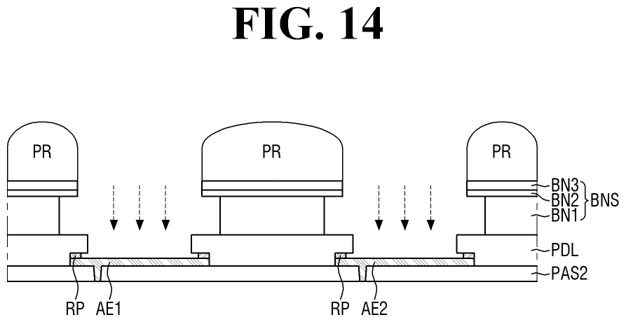

Next, as shown in FIG. 13, the pixel defining material layer PDLL may be removed by a fourth etching process (4^{th} etching) to expose the sacrificial layer SFL as per step S50 of FIG. 8. As shown in FIG. 14, the sacrificial layer SFL may be etched by a fifth etching process (5^{th} etching) to expose the pixel electrodes AE1, AE2, and AE3 as per step S60 of FIG. 8.

The portion of the sacrificial layer SFL that may be exposed by the hole HOL, and a part of the sacrificial layer SFL between the first bank material layer BNL1 and the pixel electrodes AE1, AE2, and AE3 may be removed. However, the sacrificial layer SFL may not be completely removed, and may remain as the partial residual pattern RP between the pixel defining layer PDL and the pixel electrodes AE1, AE2, and AE3. A space may be formed, as a portion remaining after the removal of the sacrificial layer SFL, between the pixel electrodes AE1, AE2, and AE3 and the pixel defining layer PDL disposed thereon. In a subsequent process, the light emitting layers EL1, EL2, and EL3 disposed on the pixel electrodes AE1, AE2, and AE3 may be formed to fill the space.

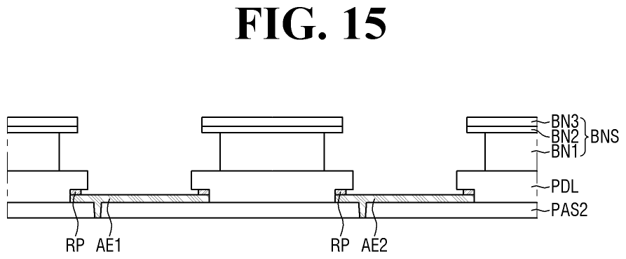

Next, as shown in FIG. 15, the photoresist PR may be removed from the third bank layer BN3.

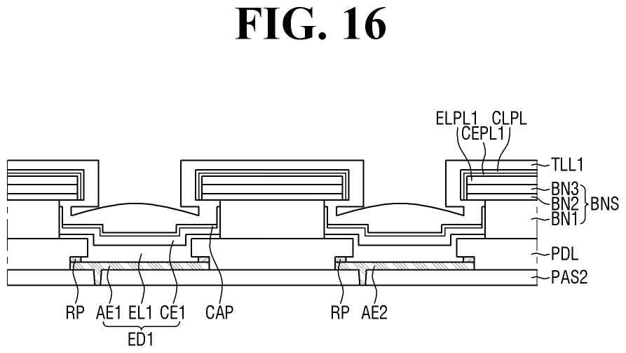

Next, as shown in FIG. 16, the first light emitting layer EL1, the first common electrode CE1, and the capping layer CAP may be deposited on the first pixel electrode AE1 to form the first light emitting element ED1 as per step S70 of FIG. 8. The first light emitting layer EL1, the first common electrode CE1, and the capping layer CAP may be formed on the entire surface of the substrate SUB, so that the trace pattern may be formed on the third bank layer BN3.

Due to the tips TIP of the second and third bank layers BN2 and BN3, the first light emitting layer EL1 and the first organic pattern material layer ELPL1 may be spaced apart (or separated) from each other, the first common electrode CE1 and the first electrode pattern material layer CEPL1 may be spaced apart (or separated) from each other, and the capping layer CAP and the capping pattern material layer CLPL may be spaced apart (or separated) from each other. The first light emitting layer EL1 may be formed on the first pixel electrode AE1, and the first organic pattern material layer ELPL1 may be formed on the third bank layer BN3. The first common electrode CE1 may be formed on the first light emitting layer EL1, and the first electrode pattern material layer CELP1 may be formed on the first organic pattern material layer ELPL1 as per step S70 of FIG. 8.

The first light emitting layer EL1 and the first common electrode CE1 may be formed by a deposition process. In the opening, the deposition of the material may not be smooth due to the tips TIP of the second and third bank layers BN2 and BN3. Since, however, the materials of the first light emitting layer EL1 and the first common electrode CE1 may be deposited in an inclined direction rather than in a direction perpendicular to the top surface of the substrate, they may be deposited even in the region hidden by the tips TIP of the second and third bank layers BN2 and BN3.

The deposition process of forming the common electrodes CE1, CE2, and CE3 may be performed at an angle inclined to be relatively closer to a horizontal direction compared to the deposition process of forming the light emitting layers EL1, EL2, and EL3. Accordingly, the common electrodes CE1, CE2, and CE3 may be in contact with the side surface of the first bank layer BN1 in larger areas compared to the light emitting layers EL1, EL2, and EL3. Alternatively, the common electrodes CE1, CE2, and CE3 may be deposited to higher positions on the side surface of the first bank layer BN1 compared to the light emitting layers EL1, EL2, and EL3. The different common electrodes CE1, CE2, and CE3 may be electrically connected to each other while being in contact with the second bank layer BN2 having high conductivity.

Next and as illustrated in FIG. 16, a first inorganic material layer TLL1 covering the first light emitting element ED1 and the capping layer CAP may be formed. The first inorganic material layer TLL1 may be formed to completely and seamlessly cover the outer surfaces of the first light emitting element ED1, the bank layers BN1 and BN2, the capping layer CAP, and the trace pattern. Specifically, the first inorganic material layer TLL1 may be formed on the top surface of the first common electrode CE1, the side surface of the first bank layer BN1, the bottom surface of the second bank layer BN2, the top surface of the third bank layer BN3, and the top surface of the trace pattern.

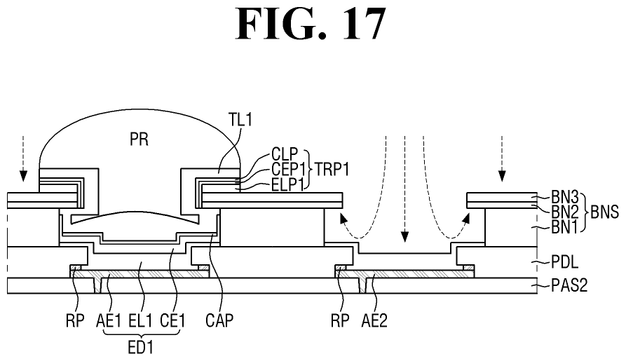

Referring to FIG. 17, the photoresist PR of a mask pattern may be formed on the first inorganic material layer TLL1, and a sixth etching process (6^{th} etching) for removing the first inorganic material layer TLL1 and the trace pattern that may not be covered with the mask pattern may be performed as per step S80 of FIG. 8. The photoresist PR may be disposed to overlap the first emission area EA1 and the edge area surrounding the first emission area EA1.

In an embodiment, the sixth etching process may be dry etching using a fluorine-based gas. Although the bottom surface of the tip TIP of the second bank layer BN2 of the second and third emission areas EA2 and EA3 may be exposed by the fluorine-based gas, zinc (Zn) of the second bank layer BN2 may be stable without reacting to the fluorine-based gas. In spite of repeated etching processes, the shape of the tip TIP may be maintained without being damaged.

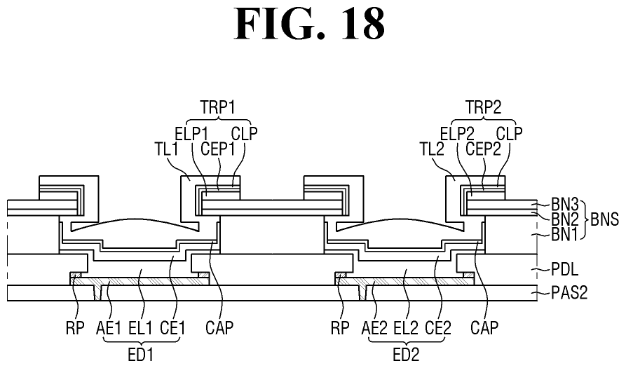

Next, the photoresist PR may be removed and the process similar to that of FIG. 16 may be performed, so that the second light emitting element ED2 and the second inorganic layer TL2 may be formed on the second emission area EA2, and the trace pattern may be formed on the third bank layer BN3. The second light emitting layer EL2, the second common electrode CE2, the capping layer CAP, and a second inorganic material layer may be formed on the first inorganic layer TL1 on the first emission area EA1. As shown in FIG. 17, the photoresist PR of the mask pattern may be formed to overlap the second emission area EA2. The process of removing the second inorganic material layer and the trace pattern that may not be covered with the mask pattern may be repeated to obtain the second light emitting element ED2 and the second trace pattern TRP2 as shown in FIG. 18.

Although not shown in the drawing, the display device 10 may be fabricated by forming the organic encapsulation layer TFE2 and the second inorganic encapsulation layer TFE3 of the thin film encapsulation layer TFEL, the light blocking layer BM, the color filter layer CFL, and the overcoat layer OC on the light emitting elements ED1, ED2, and ED3 and the bank structure BNS. The description of the structure of the thin film encapsulation layer TFEL, the light blocking layer BM, the color filter layer CFL, and the overcoat layer OC may be the same as described above, so that the detailed description thereof will be omitted.

In concluding the detailed description, those skilled in the art will appreciate that many variations and modifications can be made to the embodiments without substantially departing from the principles of the invention. Therefore, the disclosed embodiments of the disclosure may be used in a generic and descriptive sense only and not for purposes of limitation.

What is claimed is:

1. A display device comprising:
a first pixel electrode disposed on a substrate;
a pixel defining layer disposed on the substrate and exposing the first pixel electrode;
a first light emitting layer disposed on the first pixel electrode;
a first common electrode disposed on the first light emitting layer;
a first bank layer disposed on the pixel defining layer;
a second bank layer disposed on the first bank layer and comprising a side surface protruding from a side surface of the first bank layer; and
a third bank layer disposed on the second bank layer and comprising a side surface protruding from the side surface of the first bank layer, wherein
the second bank layer and the third bank layer each comprise a transparent conductive oxide (TCO), and
the second bank layer further comprises zinc (Zn).

2. The display device of claim 1, wherein the third bank layer further comprises hydrogen.

3. The display device of claim 1, wherein a ratio of zinc (Zn) in the second bank layer is in a range of about 5 at % to about 50 at % with respect to a total number of atoms.

4. The display device of claim 1, wherein the side surface of the second bank layer and the side surface of the third bank layer are aligned with each other in a plan view.

5. The display device of claim 1, wherein
the second bank layer and the third bank layer are amorphous, and
a combined visible light transmittance of the second bank layer and the third bank layer is about 85% or more.

6. The display device of claim 1, wherein the third bank layer comprises hydrogen and indium tin oxide (ITO).

7. The display device of claim 1, wherein a thickness of the third bank layer is greater than a thickness of the second bank layer.

8. The display device of claim 1, wherein a sum of a thickness of the second bank layer and a thickness of the third bank layer is in a range of about 500 Å to about 1500 Å.

9. The display device of claim 1, wherein the first bank layer comprises metal.

10. The display device of claim 1, wherein the first common electrode is in contact with the first bank layer.

11. The display device of claim 1, wherein a thickness of the first bank layer is in a range of about 4000 Å to about 7000 Å.

12. The display device of claim 1, further comprising:
a first organic pattern disposed on the third bank layer, wherein the first organic pattern and the first light emitting layer comprise a same material; and
a first electrode pattern disposed on the first organic pattern, wherein the first electrode pattern and the first common electrode comprise a same material, wherein
the first light emitting layer and the first organic pattern are spaced apart from each other, and
the first common electrode and the first electrode pattern are spaced apart from each other.

13. A display device comprising:
a first pixel electrode disposed on a substrate;
a pixel defining layer disposed on the substrate and exposing the first pixel electrode;
a first light emitting layer disposed on the first pixel electrode;
a first common electrode disposed on the first light emitting layer;
a first bank layer disposed on the pixel defining layer;
a second bank layer disposed on the first bank layer and comprising a side surface protruding from a side surface of the first bank layer; and
a third bank layer disposed on the second bank layer and comprising a side surface protruding from the side surface of the first bank layer, wherein
a thickness of the first bank layer is greater than a sum of a thickness of the second bank layer and a thickness of the third bank layer, and
the thickness of the third bank layer is greater than the thickness of the second bank layer.

14. The display device of claim 13, wherein
the first bank layer comprises an opaque metal, and
the second bank layer and the third bank layer each comprise a transparent conductive oxide (TCO).

15. The display device of claim 13, wherein the thickness of the first bank layer is greater than or equal to about three times the sum of the thickness of the second bank layer and the thickness of the third bank layer.

16. The display device of claim 13, further comprising:
a second pixel electrode disposed on the substrate wherein the second pixel electrode and the first pixel electrode are spaced apart from each other;
a second light emitting layer disposed on the second pixel electrode;
a second common electrode disposed on the second light emitting layer wherein the second common electrode and the first common electrode are spaced apart from each other;
a first inorganic layer disposed on each of the first common electrode and the third bank layer; and
a second inorganic layer disposed on each of the second common electrode and the third bank layer, wherein
the first inorganic layer and the second inorganic layer are spaced apart from each other,
a part of the third bank layer is exposed in a separation space between the first inorganic layer and the second inorganic layer, and
a thickness of the second bank layer overlapping the first inorganic layer and a thickness of the second bank layer overlapping the second inorganic layer are equal.

17. A method for fabrication of a display device, comprising:
forming a plurality of pixel electrodes spaced apart from each other on a substrate;
forming a sacrificial layer on the plurality of pixel electrodes;
forming a pixel defining material layer on the sacrificial layer;
forming a first bank material layer on the pixel defining material layer;
forming a second bank material layer on the first bank material layer;
forming a third bank material layer on the second bank material layer;
etching the second bank material layer and the third bank material layer in an area overlapping the plurality of pixel electrodes;
etching the first bank material layer in the area overlapping the plurality of pixel electrodes;
etching a side surface of the first bank material layer to partially expose a bottom surface of the second bank material layer;
etching the pixel defining material layer;
etching the sacrificial layer to expose the plurality of pixel electrodes;
forming a first light emitting layer on one of the plurality of pixel electrodes;
forming a first common electrode on the first light emitting layer; and
forming a first inorganic material layer on the first common electrode.

18. The method of claim 17, wherein
the forming of the third bank material layer on the second bank material layer comprises sputtering under a mixed gas atmosphere comprising hydrogen and argon, and
the third bank material layer comprises hydrogen and indium tin oxide (ITO).

19. The method of claim 17, wherein
the etching of the second bank material layer and the third bank material layer in the area overlapping the plurality of pixel electrodes comprises exposing a part of the first bank material layer by removing the second bank material layer and the third bank material layer through a wet etching technique, and
the etching of the first bank material layer in the area overlapping the plurality of pixel electrodes comprises removing the exposed part of the first bank material layer by a dry etching technique.

20. The method of claim 17, wherein
the forming of the first light emitting layer on the one of the plurality of pixel electrodes comprises forming a first organic pattern material layer on the third bank material layer, the first organic pattern material layer being spaced apart from the first light emitting layer,
the forming of the first common electrode on the first light emitting layer comprises forming a first electrode pattern material layer on the first organic pattern material layer, the first electrode pattern material layer being spaced apart from the first common electrode, and
the forming of the first inorganic material layer on the first common electrode comprises forming the first inorganic material layer seamlessly connected on the first common electrode and the first electrode pattern material layer.
